(19) United States
(12) Patent Application Publication
(10) Pub. No.: US 2020/0002222 A1
(43) Pub. Date: Jan. 2, 2020

(54) METHODS FOR REDUCING GLASS SHEET EDGE PARTICLES

(71) Applicant: Corning Incorporated, Corning, NY (US)

(72) Inventors: Jia Liu, Painted Post, NY (US); Siva Venkatachalam, Elmira, NY (US); Jing Zhao, San Diego, CA (US)

(21) Appl. No.: 16/482,548

(22) PCT Filed: Jan. 31, 2018
(86) PCT No.: PCT/US2018/016198

§ 371 Date: Jul. 31, 2019

Related U.S. Application Data
(60) Provisional application No. 62/452,674, filed on Jan. 31, 2017.

(51) Int. Cl. C03C 15/00; H05K 5/03; C09K 13/06; C09K 13/08

(52) U.S. Cl. CPC C03C 15/00; C09K 13/08; C09K 13/06; H05K 5/03

(57) ABSTRACT

A method of manufacturing a glass article includes application of an etch cream to an edge surface of the article. Application of the etch cream can reduce a density of particles on the edge surface to less than about 200 per 0.1 square millimeter. The etch cream can, for example, contain hydrofluoric acid, hydrochloric acid and a thickener.

This application claims the benefit of priority under 35 U.S.C. § 119 of U.S. Provisional Application Ser. No. 62/452,674 filed on Jan. 31, 2017, the contents of which are relied upon and incorporated herein by reference in their entirety as if fully set forth below.

### FIELD

The present disclosure relates generally to methods for manufacturing glass articles and more particularly to methods for reducing glass sheet edge particles in the manufacture of glass articles.

### BACKGROUND

In the production of glass articles, such as glass sheets for display applications, including televisions and hand held devices, such as telephones and tablets, the glass articles must meet increasingly stringent requirements for surface contamination, specifically substantially low levels of, for example, organic stains dust, and glass particles on the surfaces of the articles. These increasingly stringent requirements have, for example, been driven by increasing resolution levels of display devices, which, with ever decreasing pixel sizes, are increasingly sensitive to particles.

During the production of glass articles there are many processing steps during which, for example, glass and dust particles may adhere to not only the surfaces but also the edges of glass sheets. While much attention has been given to reducing the number of particles on the surfaces of glass sheets, relatively less attention has been given to reducing the number of particles on the edges of glass sheets.

As particles may migrate from the edges to the surfaces of glass sheets, recent efforts have focused on mechanical methods for reducing edge particles, such as edge cleaning wheels. However, such mechanical methods may only remove existing particles, while further particles may be generated due to effects of downstream processing steps on edge surface topography. Accordingly, it would be desirable to develop edge cleaning methods that not only address removal of existing particles but also mitigate the further generation of particles as the result of downstream processing steps.

### SUMMARY

Embodiments disclosed herein include a method for manufacturing a glass article. The method includes forming the glass article. The glass article includes a first major surface, a second major surface parallel to the first major surface, and an edge surface extending between the first major surface and the second major surface in a perpendicular direction to the first and second major surfaces. The method also includes applying an etch cream to the edge surface of the glass article, wherein application of the etch cream reduces a density of particles on the edge surface.

Additional features and advantages of the embodiments disclosed herein will be set forth in the detailed description which follows, and in part will be readily apparent to those skilled in the art from that description or recognized by practicing the disclosed embodiments as described herein, including the detailed description which follows, the claims, as well as the appended drawings.

It is to be understood that both the foregoing general description and the following detailed description present embodiments intended to provide an overview or framework for understanding the nature and character of the claimed embodiments. The accompanying drawings are included to provide further understanding, and are incorporated into and constitute a part of this specification. The drawings illustrate various embodiments of the disclosure, and together with the description serve to explain the principles and operations thereof.

### BRIEF DESCRIPTION OF THE DRAWINGS

FIG. 1 is a schematic view of an example fusion down draw glass making apparatus and process;

FIG. 2 is an perspective view of a glass sheet;

FIG. 3 is a perspective view of at least a portion of a beveling process of an edge surface of a glass sheet;

FIG. 4 is a chart showing etch rate of different applications of etch cream and etch solution to glass; and

FIGS. 5A-5D show cross-sectional scanning electron microscope (SEM) images of glass samples comparing an untreated sample with samples treated with etch creams and an etch solution.

### DETAILED DESCRIPTION

Reference will now be made in detail to the present preferred embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, for example by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, the term “etch cream” refers to a composition having a dynamic viscosity of at least about 10 poise at a temperature of 45° C. and a dynamic shear rate of 1 Hz that is capable of etching glass For example, etch creams, as disclosed herein may include etch solutions thickened with at least one thickener.

As used herein, the term “dynamic shear rate” refers to a rate in Hz (cycles per second) at which members move relative to each other between which a composition (e.g., an etch cream) is disposed. For example, in embodiments disclosed herein, dynamic shear rate was determined by disposing a composition (e.g., an etch cream) between two parallel plates and keeping one plate fixed while moving the other plate at an approximately constant speed.

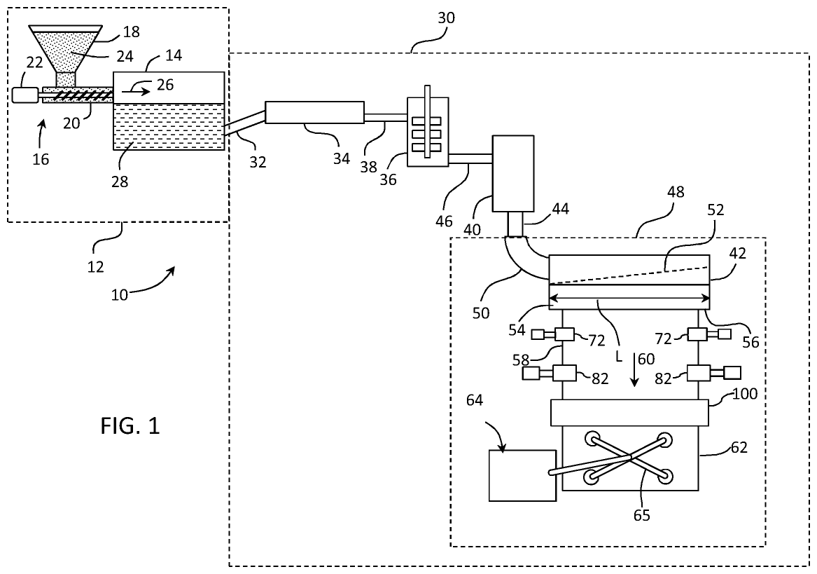

Shown in FIG. 1 is an exemplary glass manufacturing apparatus 10. In some examples, the glass manufacturing apparatus 10 can comprise a glass melting furnace 12 that can include a melting vessel 14. In addition to melting vessel 14, glass melting furnace 12 can optionally include one or more additional components such as heating elements (e.g., combustion burners or electrodes) that heat raw materials and convert the raw materials into molten glass. In further examples, glass melting furnace 12 may include thermal management devices (e.g., insulation components) that reduce heat lost from a vicinity of the melting vessel. In still further examples, glass melting furnace 12 may include electronic devices and/or electromechanical devices that facilitate melting of the raw materials into a glass melt. Still further, glass melting furnace 12 may include support structures (e.g., support chassis, support member, etc.) or other components.

Glass melting vessel 14 is typically comprised of refractory material, such as a refractory ceramic material, for example a refractory ceramic material comprising alumina or zirconia. In some examples glass melting vessel 14 may be constructed from refractory ceramic bricks. Specific embodiments of glass melting vessel 14 will be described in more detail below.

In some examples, the glass melting furnace may be incorporated as a component of a glass manufacturing apparatus to fabricate a glass substrate, for example a glass ribbon of a continuous length. In some examples, the glass melting furnace of the disclosure may be incorporated as a component of a glass manufacturing apparatus comprising a slot draw apparatus, a float bath apparatus, a down-draw apparatus such as a fusion process, an up-draw apparatus, a press-rolling apparatus, a tube drawing apparatus or any other glass manufacturing apparatus that would benefit from the aspects disclosed herein. By way of example, FIG. 1 schematically illustrates glass melting furnace 12 as a component of a fusion down-draw glass manufacturing apparatus 10 for fusion drawing a glass ribbon for subsequent processing into individual glass sheets.

The glass manufacturing apparatus 10 (e.g., fusion down-draw apparatus 10) can optionally include an upstream glass manufacturing apparatus 16 that is positioned upstream relative to glass melting vessel 14. In some examples, a portion of, or the entire upstream glass manufacturing apparatus 16, may be incorporated as part of the glass melting furnace 12.

As shown in the illustrated example, the upstream glass manufacturing apparatus 16 can include a storage bin 18, a raw material delivery device 20 and a motor 22 connected to the raw material delivery device. Storage bin 18 may be configured to store a quantity of raw materials 24 that can be fed into melting vessel 14 of glass melting furnace 12, as indicated by arrow 26. Raw materials 24 typically comprise one or more glass forming metal oxides and one or more modifying agents. In some examples, raw material delivery device 20 can be powered by motor 22 such that raw material delivery device 20 delivers a predetermined amount of raw materials 24 from the storage bin 18 to melting vessel 14. In further examples, motor 22 can power raw material delivery device 20 to introduce raw materials 24 at a controlled rate based on a level of molten glass sensed downstream from melting vessel 14. Raw materials 24 within melting vessel 14 can thereafter be heated to form molten glass 28.

Glass manufacturing apparatus 10 can also optionally include a downstream glass manufacturing apparatus 30 positioned downstream relative to glass melting furnace 12. In some examples, a portion of downstream glass manufacturing apparatus 30 may be incorporated as part of glass melting furnace 12. In some instances, first connecting conduit 32 discussed below, or other portions of the downstream glass manufacturing apparatus 30, may be incorporated as part of glass melting furnace 12. Elements of the downstream glass manufacturing apparatus, including first connecting conduit 32, may be formed from a precious metal. Suitable precious metals include platinum group metals selected from the group of metals consisting of platinum, iridium, rhodium, osmium, ruthenium and palladium, or alloys thereof. For example, downstream components of the glass manufacturing apparatus may be formed from a platinum-rhodium alloy including from about 70 to about 90% by weight platinum and about 10% to about 30% by weight rhodium. However, other suitable metals can include molybdenum, palladium, rhenium, tantalum, titanium, tungsten and alloys thereof.

Downstream glass manufacturing apparatus 30 can include a first conditioning (i.e., processing) vessel, such as fining vessel 34, located downstream from melting vessel 14 and coupled to melting vessel 14 by way of the above-referenced first connecting conduit 32. In some examples, molten glass 28 may be gravity fed from melting vessel 14 to fining vessel 34 by way of first connecting conduit 32. For instance, gravity may cause molten glass 28 to pass through an interior pathway of first connecting conduit 32 from melting vessel 14 to fining vessel 34. It should be understood, however, that other conditioning vessels may be positioned downstream of melting vessel 14, for example between melting vessel 14 and fining vessel 34. In some embodiments, a conditioning vessel may be employed between the melting vessel and the fining vessel wherein molten glass from a primary melting vessel is further heated to continue the melting process, or cooled to a temperature lower than the temperature of the molten glass in the melting vessel before entering the fining vessel.

Bubbles may be removed from molten glass 28 within fining vessel 34 by various techniques. For example, raw materials 24 may include multivalent compounds (i.e. fining agents) such as tin oxide that, when heated, undergo a chemical reduction reaction and release oxygen. Other suitable fining agents include without limitation arsenic, antimony, iron and cerium. Fining vessel 34 is heated to a temperature greater than the melting vessel temperature, thereby heating the molten glass and the fining agent. Oxygen bubbles produced by the temperature-induced chemical reduction of the fining agent(s) rise through the molten glass within the fining vessel, wherein gases in the molten glass produced in the melting furnace can diffuse or coalesce into the oxygen bubbles produced by the fining agent. The enlarged gas bubbles can then rise to a free surface of the molten glass in the fining vessel and thereafter be vented out of the fining vessel. The oxygen bubbles can further induce mechanical mixing of the molten glass in the fining vessel.

Downstream glass manufacturing apparatus 30 can further include another conditioning vessel such as a mixing vessel 36 for mixing the molten glass. Mixing vessel 36 may be located downstream from the fining vessel 34. Mixing vessel 36 can be used to provide a homogenous glass melt composition, thereby reducing cords of chemical or thermal inhomogeneity that may otherwise exist within the fined molten glass exiting the fining vessel. As shown, fining vessel 34 may be coupled to mixing vessel 36 by way of a second connecting conduit 38. In some examples, molten glass 28 may be gravity fed from the fining vessel 34 to mixing vessel 36 by way of second connecting conduit 38. For instance, gravity may cause molten glass 28 to pass through an interior pathway of second connecting conduit 38 from fining vessel 34 to mixing vessel 36. It should be noted that while mixing vessel 36 is shown downstream of fining vessel 34, mixing vessel 36 may be positioned upstream from fining vessel 34. In some embodiments, downstream glass manufacturing apparatus 30 may include multiple mixing vessels, for example a mixing vessel upstream from fining vessel 34 and a mixing vessel downstream from fining vessel 34. These multiple mixing vessels may be of the same design, or they may be of different designs.

Downstream glass manufacturing apparatus 30 can further include another conditioning vessel such as delivery vessel 40 that may be located downstream from mixing vessel 36. Delivery vessel 40 may condition molten glass 28 to be fed into a downstream forming device. For instance, delivery vessel 40 can act as an accumulator and/or flow controller to adjust and/or provide a consistent flow of molten glass 28 to forming body 42 by way of exit conduit 44. As shown, mixing vessel 36 may be coupled to delivery vessel 40 by way of third connecting conduit 46. In some examples, molten glass 28 may be gravity fed from mixing vessel 36 to delivery vessel 40 by way of third connecting conduit 46. For instance, gravity may drive molten glass 28 through an interior pathway of third connecting conduit 46 from mixing vessel 36 to delivery vessel 40.

Downstream glass manufacturing apparatus 30 can further include forming apparatus 48 comprising the above-referenced forming body 42 and inlet conduit 50. Exit conduit 44 can be positioned to deliver molten glass 28 from delivery vessel 40 to inlet conduit 50 of forming apparatus 48. For example in examples, exit conduit 44 may be nested within and spaced apart from an inner surface of inlet conduit 50, thereby providing a free surface of molten glass positioned between the outer surface of exit conduit 44 and the inner surface of inlet conduit 50. Forming body 42 in a fusion down draw glass making apparatus can comprise a trough 52 positioned in an upper surface of the forming body and converging forming surfaces 54 that converge in a draw direction along a bottom edge 56 of the forming body. Molten glass delivered to the forming body trough via delivery vessel 40, exit conduit 44 and inlet conduit 50 overflows side walls of the trough and descends along the converging forming surfaces 54 as separate flows of molten glass. The separate flows of molten glass join below and along bottom edge 56 to produce a single ribbon of glass 58 that is drawn in a draw or flow direction 60 from bottom edge 56 by applying tension to the glass ribbon, such as by gravity, edge rolls 72 and pulling rolls 82, to control the dimensions of the glass ribbon as the glass cools and a viscosity of the glass increases. Accordingly, glass ribbon 58 goes through a visco-elastic transition and acquires mechanical properties that give the glass ribbon 58 stable dimensional characteristics. Glass ribbon 58 may, in some embodiments, be separated into individual glass sheets 62 by a glass separation apparatus 100 in an elastic region of the glass ribbon. A robot 64 may then transfer the individual glass sheets 62 to a conveyor system using gripping tool 65, whereupon the individual glass sheets may be further processed.

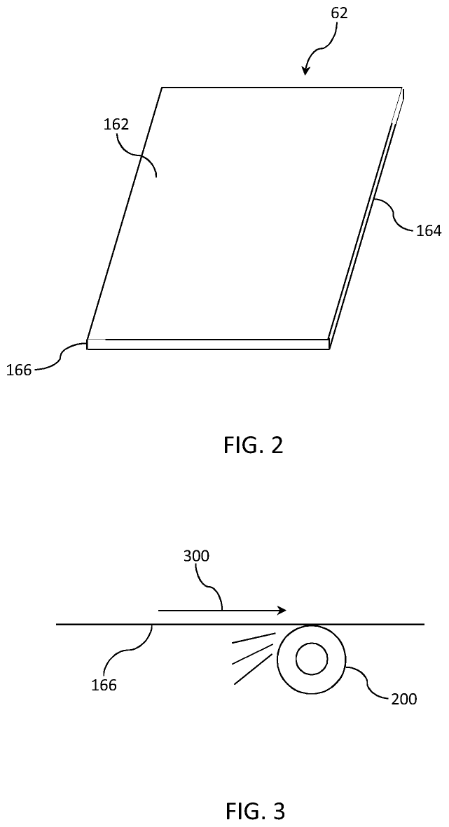

FIG. 2 shows a perspective view of a glass sheet 62 having a first major surface 162, a second major surface 164 extending in a generally parallel direction to the first major surface (on the opposite side of the glass sheet 62 as the first major surface) and an edge surface 166 extending between the first major surface and the second major surface and extending in a generally perpendicular direction to the first and second major surfaces 162, 164.

FIG. 3 shows a perspective view of at least a portion of a beveling process of an edge surface 166 of a glass sheet 62. As shown in FIG. 3, beveling process includes applying a grinding wheel 200 to edge surface 166, wherein the grinding wheel 200 moves along edge surface 166 in the direction indicated by arrow 300. Beveling process may further include applying at least one polishing wheel (not shown) to edge surface 166. Such beveling process can lead to the presence of numerous glass particles, as well as surface and sub-surface damage (i.e., irregular topography), on edge surface 166.

Downstream processing of glass sheet 62 may involve application of mechanical or chemical treatments on edge surfaces 166, which can result in additional particle generation due to the presence of irregular edge surface topography. Such particles may migrate to at least one surface of glass sheets 62. Accordingly, embodiments disclosed herein include those in which irregular edge surface topography is removed, while at the same time removing edge particles present on the edge surfaces 166 as well as removing reaction by-products that may be formed upon removal of the irregular edge surface topography.

Embodiments disclosed herein include those in which an etch cream is applied to an edge surface 166 of glass sheet 62, including those in which the edge surface 166 is subjected to a beveling process, such as shown in FIG. 3, prior to application of the etch cream.

In certain exemplary embodiments, the etch cream may comprise hydrofluoric acid and hydrochloric acid. For example, in certain exemplary embodiments, the etch cream may comprise an etch solution comprising hydrofluoric and hydrochloric acid in combination with a thickener.

In certain exemplary embodiments, the etch cream may consist essentially of hydrofluoric acid, hydrochloric acid, and a thickener. For example, in certain exemplary embodiments, the etch cream may consist essentially of an aqueous solution consisting essentially of water, hydrofluoric acid, and hydrochloric acid in combination with a thickener.

The thickener, while not limited, should preferably be selected such that the etch cream will not substantially degrade in a low pH environment. For example, the thickener may comprise at least one component selected from the group consisting of polyacrylamides, polyethylene oxides, and ether amines. An exemplary polyacrylamide is Polyacrylamide (Mw 600,000-1,000,000) available from Polysciences, Inc. An exemplary polyethylene oxide is POLYOX™ available from Dow Chemical. An exemplary ether amine is Tomamine® Acid Thickener available from Air Products.

The thickener can be combined with an etch solution such that the resulting etch cream has a viscosity within a predetermined range. For example, the etch cream may comprise at least about 10% thickener by weight, such as at least 15% thickener by weight, and further such as at least about 20% thickener by weight, including from about 10% to about 30% thickener by weight, such as from about 15% to about 25% thickener by weight, including about 20% thickener by weight. Such embodiments include those in which an etch solution makes up the balance of the etch cream.

Embodiments disclosed herein include those in which the etch cream has a dynamic viscosity of at least about 10 poise, such as at least 20 poise, and further such as at least 50 poise, and yet further such as at least 100 poise, including from about 10 poise to about 200 poise, such as from about 20 poise to about 100 poise at a temperature of 45° C. and a dynamic shear rate of 1 Hz.

When the etch cream contains hydrofluoric acid and hydrochloric acid, the concentration of the hydrochloric acid in the etch cream may, for example, be equal to or greater than the concentration of the hydrofluoric acid in the etch cream, such as at least about twice the concentration of the hydrofluoric acid in the etch cream, and further such as at least about three times the concentration of the hydrofluoric acid in the etch cream, and yet further such as at least about four times the concentration of the hydrofluoric acid in the etch cream, and still yet further such as at least about five times the concentration of the hydrofluoric acid in the etch cream. For example, the concentration ratio of hydrochloric acid to hydrofluoric acid in the etch cream may range from about 1:1 to about 6:1, such as from about 2:1 to about 5:1.

In such embodiments, the concentration of the hydrofluoric acid in the etch solution of the etch cream may be at least about 1.5 molar, such as at least about 2 molar, and further such as at least about 2.5 molar, and yet further such as at least 3 molar. For example, the concentration of hydrofluoric acid in the etch solution of the etch cream may range from about 1.5 to about 6 molar, such as from about 2 to about 4 molar.

Embodiments disclosed herein include those in which the concentration of the hydrochloric acid in the etch solution of the etch cream may be at least about 1.5 molar, such as at least about 3 molar, and further such as at least about 4.5 molar, and yet further such as at least about 6 molar, and still yet further such as at least about 7.5 molar. For example, the concentration of hydrochloric acid in the etch solution of the etch cream may range from about 1.5 to about 12 molar, such as from about 3 to about 12 molar, and further such as from about 4.5 to about 9 molar.

Accordingly, embodiments disclosed herein include those in which the concentration of hydrofluoric acid in the etch solution of the etch cream is at least about 1.5 molar and the concentration of hydrochloric acid in the etch solution of the etch cream is at least about 1.5 molar.

Embodiments disclosed herein also include those in which the concentration of hydrofluoric acid in the etch solution of the etch cream is at least about 1.5 molar and the concentration of hydrochloric acid in the etch solution of the etch cream is at least about 3 molar.

Embodiments disclosed herein also include those in which the concentration of hydrofluoric acid in the etch solution of the etch cream is at least about 1.5 molar and the concentration of hydrochloric acid in the etch solution of the etch cream is at least about 4.5 molar.

Embodiments disclosed herein also include those in which the concentration of hydrofluoric acid in the etch solution of the etch cream is at least about 1.5 molar and the concentration of hydrochloric acid in the etch solution of the etch cream is at least about 6 molar.

Embodiments disclosed herein also include those in which the concentration of hydrofluoric acid in the etch solution of the etch cream is at least about 1.5 molar and the concentration of hydrochloric acid in the etch solution of the etch cream is at least about 7.5 molar.

Embodiments disclosed herein also include those in which the concentration of hydrofluoric acid in the etch solution of the etch cream is at least about 3 molar and the concentration of hydrochloric acid in the etch solution of the etch cream is at least about 3 molar.

Embodiments disclosed herein also include those in which the concentration of hydrofluoric acid in the etch solution of the etch cream is at least about 3 molar and the concentration of hydrochloric acid in the etch solution of the etch cream is at least about 6 molar.

Embodiments disclosed herein also include those in which the concentration of hydrofluoric acid in the etch solution of the etch cream ranges from about 1.5 to about 6 molar and the concentration of hydrochloric acid in the etch solution of the etch cream ranges from about 1.5 to about 12 molar.

Embodiments disclosed herein also include those in which the concentration of hydrofluoric acid in the etch solution of the etch cream ranges from about 1.5 to about 6 molar and the concentration of hydrochloric acid in the etch solution ranges from about 3 molar to about 12 molar.

Embodiments disclosed herein also include those in which the concentration of hydrofluoric acid in the etch solution of the etch cream ranges from about 1.5 to about 6 molar and the concentration of hydrochloric acid in the etch solution of the etch cream ranges from about 4.5 molar to about 9 molar.

In certain exemplary embodiments disclosed herein, including embodiments described above, the etch cream may applied to an edge surface 166 of glass sheet 62 at a temperature of at least about 45° C., such as at least about 50° C., and further such as at least about 55° C. For example, the etch cream may be applied to an edge surface 166 of glass sheet 62 at a temperature ranging from about 45° C. to about 60° C., such as from about 50° C. to about 55° C.

In certain exemplary embodiments disclosed herein, including embodiments described above, the etch cream may applied to an edge surface 166 of glass sheet 62 for a time of at least about 30 seconds, such as at least about 60 seconds, and further such as at least about 90 seconds, including about 120 seconds. For example, the etch cream may be applied to an edge surface 166 of glass sheet 62 for a time ranging from about 30 seconds to about 120 seconds, such as from about 30 seconds to about 60 seconds.

Accordingly, embodiments disclosed herein include those in which the etch solution of the etch cream comprises hydrofluoric and hydrochloric acid, the concentration of the hydrofluoric acid in the etch solution is at least about 1.5 molar, the concentration of the hydrochloric acid in the etch solution is at least about 1.5 molar, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution is at least about 1.5 molar, the concentration of the hydrochloric acid in the etch solution is at least about twice the concentration of the hydrofluoric acid in the etch solution, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution of the is at least about 1.5 molar, the concentration of the hydrochloric acid in the etch solution is at least about three times the concentration of the hydrofluoric acid in the etch solution, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution is at least about 1.5 molar, the concentration of the hydrochloric acid in the etch solution is at least about four times the concentration of the hydrofluoric acid in the etch solution, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution is at least about 1.5 molar, the concentration of the hydrochloric acid in the etch solution is at least about five times the concentration of the hydrofluoric acid in the etch solution, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution is at least about 3 molar, the concentration of the hydrochloric acid in the etch solution is at least about twice the concentration of the hydrofluoric acid in the etch solution, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric acid and hydrochloric acid, the concentration of the hydrofluoric acid in the etch solution is at least about 1.5 molar, the concentration of the hydrochloric acid in the etch solution is at least about 7.5 molar, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric acid and hydrochloric acid, the concentration of the hydrofluoric acid in the etch solution is at least about 3 molar, the concentration of the hydrochloric acid in the etch solution is at least about 6 molar, and the etch cream is applied to an edge surface of a glass sheet at a solution temperature of at least about 45° C. and for a time of at least about 30 seconds.

Embodiments disclosed herein also include those in which the etch solution of the etch cream comprises hydrofluoric and hydrochloric acid, the concentration of the hydrofluoric acid in the etch solution ranges from about 1.5 molar to about 6 molar, the concentration of hydrochloric acid in the etch solution ranges from about 7.5 to about 12 molar, and the etch cream is applied to an edge surface of a glass sheet at a solution temperature ranging from about 45° C. to about 60° C. and for a time ranging from about 30 seconds to about 120 seconds.

Embodiments disclosed herein also include those in which the etch solution of the etch cream comprises hydrofluoric and hydrochloric acid, the concentration of the hydrofluoric acid in the etch solution ranges from about 3 molar to about 6 molar, the concentration of hydrochloric acid in the etch solution ranges from about 6 to about 12 molar, and the etch cream is applied to an edge surface of a glass sheet at a solution temperature ranging from about 45° C. to about 60° C. and for a time ranging from about 30 seconds to about 120 seconds.

In certain exemplary embodiments disclosed herein, including embodiments described above, the etch rate of the edge surface upon application of the etch cream may be at least about 2 micrometers per minute, such as at least about 3 micrometers per minute, and further such as at least about 4 micrometers per minute, and yet further such as at least about 5 micrometers per minute. For example, the etch rate of the edge surface upon application of the etch cream may range from about 2 micrometers per minute to about 20 micrometers per minute, including from about 4 micrometers per minute to about 10 micrometers per minute.

In certain exemplary embodiments at least 1 micrometer, such as at least 2 micrometers, and further such as at least 3 micrometers, and yet further such as at least 4 micrometers, and still yet further such as at least 5 micrometers, including from about 1 micrometer to about 5 micrometers of depth of the edge surface is etched away as a result of application of the etch cream.

The etch cream may be applied to the edge surface 166 by at least one of a number of methods including, for example, spraying, misting, dipping, rolling, and brushing.

In certain exemplary embodiments, an etch cream is not substantially applied to the first and second major surfaces 162, 164 of the glass article. Specifically, in such embodiments, the etch cream is only applied to the edge surfaces of the glass article, such as a glass sheet, and not to either of the major surfaces. Accordingly, embodiments disclosed herein include those in which an etch cream is applied to the edge surfaces of a glass article but the glass article, such as a glass sheet, is not thinned by chemical etching.

Application of the etch cream can reduce a density of particles on the edge surface to less than about 200 per 0.1 square millimeter, such as less than about 150 per 0.1 square millimeter, and further such as less than about 100 per 0.1 square millimeter, and yet further such as less than about 50 per 0.1 square millimeter, including from about 1 to about 200 per 0.1 square millimeter, and further including from about 10 to about 150 per 0.1 square millimeter, and yet further including from about 20 to about 100 per 0.1 square millimeter.

Viscosity Analysis

Various etch creams were prepared, each having a different thickener at a specified concentration. The thickeners used included Polyacrylamide (Mw 600,000-1,000,000) available from Polysciences, Inc., POLYOX™ available from Dow Chemical, and Tomamine® Acid Thickener available from Air Products. Each of the etch creams were applied to an edge surface of Corning Lotus™ NXT glass to determine whether they would substantially fall off the edge within about 30 seconds at a temperature of about 45° C. The viscosity of the etch creams increased with increasing thickener concentration and etch creams containing at least about 10% by weight of Polyacrylamide had sufficient viscosity to substantially hold to the edge surface and etch creams containing at least about 20% by weight of POLYOX™ or Tomamine® had sufficient viscosity to substantially hold to the edge surface.

Etch Rate Analysis

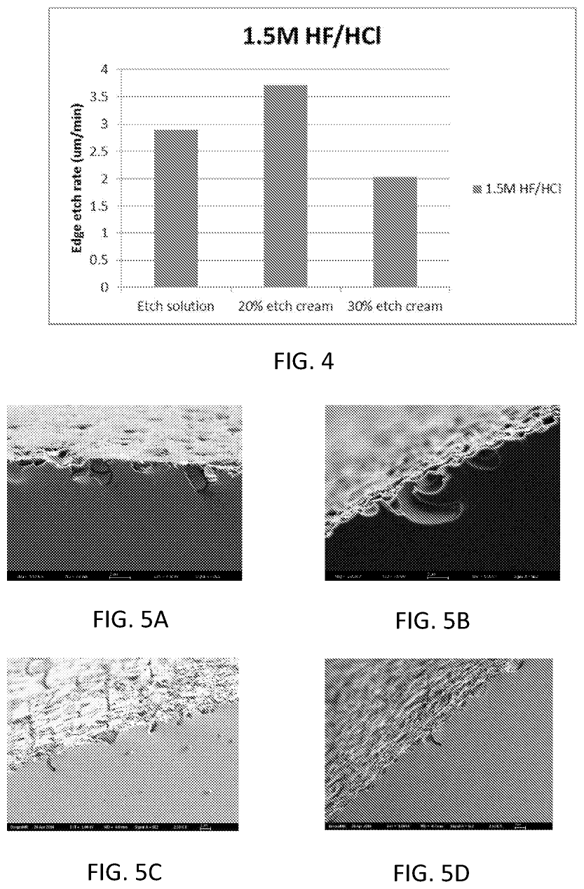

Two different etch creams were prepared, the first having a combination of about 20% by weight Tomamine® Acid Thickener and about 80% by weight of an aqueous etch solution of about 1.5 molar hydrofluoric and about 1.5 molar hydrochloric acid and the second having a combination of about 30% by weight Tomamine® Acid Thickener and about 70% by weight of an aqueous etch solution of about 1.5 molar hydrofluoric and about 1.5 molar hydrochloric acid. Each etch cream was applied to samples of Corning Lotus™ NXT glass for about 30 seconds at about 45° C. An aqueous etch solution of about 1.5 molar hydrofluoric acid and about 1.5 molar hydrochloric acid was also applied to samples of Corning Lotus™ NXT glass for about 30 seconds at about 45° C. The etch rate for each application was determined by sticking a piece of acid resistant masking tape on the flat surface of the glass before the chemical treatment and measuring the step height after the chemical treatment using a Zygo® NewView™ Optical Surface Profiler. FIG. 4 shows the etch rate comparison for the different applications. As can be seen from FIG. 4, the etch cream with about 20% thickener by weight shows a higher etch rate than the etch cream with about 30% thickener by weight. The observed reduced etch rate of the etch cream having the higher thickener concentration may be due to its relatively higher viscosity, which may result in a lower diffusion rate of its functional component.

Particle Density Analysis

The two different etch creams and the etch solution used in the etch rate analysis described above were also analyzed for their effect on particle density following application to samples of Corning Lotus™ NXT glass for about 30 seconds at about 45° C. For this analysis, a “gel-tack” method was used to determine particle density on edge surfaces of glass articles. This method involves pressing the edge surface of the glass onto a piece of tacky gel to transfer particles onto the gel, taking images of the imprinted area of the gel under an optical microscope, and then analyzing the images to determine particle density. Between the two etch creams and the etch solution, the etch cream containing about 20% by weight thickener and about 80% by weight of an aqueous etch solution of about 1.5 molar hydrofluoric and about 1.5 molar hydrochloric acid showed the lowest particle count, which was about 28 particles per 0.1 square millimeter. By comparison, the etch cream containing about 30% by weight thickener and about 70% by weight of an aqueous etch solution of about 1.5 molar hydrofluoric and about 1.5 molar hydrochloric acid showed a particle count of about 594 particles per 0.1 square millimeter, while the etch solution of about 1.5 molar hydrofluoric and about 1.5 molar hydrochloric acid showed a particle count of about 510 particles per 0.1 square millimeter.

FIGS. 5A-5D show cross-sectional SEM images of various glass samples wherein FIG. 5A shows an untreated sample of Corning Lotus™ NXT glass and FIGS. 5B-5D show images of samples of Corning Lotus™ NXT glass subjected to various treatments for about 30 seconds at about 45° C. Specifically, FIG. 5B shows an image of a glass sample treated with an aqueous etch solution of about 1.5 molar hydrofluoric and about 1.5 molar hydrochloric acid, FIG. 5C shows an image of a glass sample treated with an etch cream containing about 20% by weight Tomamine® Acid Thickener and about 80% by weight of an aqueous etch solution of about 1.5 molar hydrofluoric and about 1.5 molar hydrochloric acid, and FIG. 5D shows an image of a glass sample treated with an etch cream containing about 30% by weight Tomamine® Acid Thickener and about 70% by weight of an aqueous etch solution of about 1.5 molar hydrofluoric and about 1.5 molar hydrochloric acid. The edge surfaces treated with the etch creams showed relatively smoother surfaces than the untreated surface or the surface treated with etch solution, with the surface treated with etch cream containing about 20% thickener by weight being the smoothest.

Embodiments disclosed herein include those in which the etch cream may be washed from the edge surface following its application to the edge surface. For example, the edge surface may be washed with at least one wash solution, which may comprise a liquid, such as water (e.g., deionized water), which may or may not include at least one component to increase the solubility of the etch cream in the wash solution, such as a detergent or surfactant.

In certain exemplary embodiments the glass article may be dipped in a wash solution, such as a wash solution agitated with, for example, ultrasonic energy. The glass article may also be washed with a wash solution applied with a mechanical action, such as with a brush.

In certain exemplary embodiments, the etch cream may be washed from the edge surface by an wash solution at an elevated temperature, such as a temperature of at least about 75° C., such as a temperature ranging from about 75° C. to about 95° C. In such embodiments, the etch cream may, for example, be applied at a temperature ranging from about 45° C. to about 60° C., such that the wash solution is applied to the edge surface at a higher temperature than the etch cream.

For example, applicants have found that etch creams comprising at least about 20% thickener by weight may be removed in less than about half the time when, subsequent to their application to the edge surface of a glass article, such as a glass sheet, the glass articles are immersed in deionized water agitated with ultrasonic energy at a temperature of about 75° C. as compared to being immersed in deionized water agitated with ultrasonic energy at a temperature of about 45° C.

Embodiments disclosed herein can enable glass articles, including glass sheets, with edge surfaces having reduced particle densities, such as less than about 200 per 0.1 square millimeter, while at the same time having favorably smooth surface morphologies with substantial removal of sub-surface damage caused by, for example, beveling processes. Accordingly, embodiments disclosed herein can not only provide an advantage of relatively low edge particle densities but can also provide an additional advantage of relatively smooth surfaces that are less susceptible to additional particle generation as a result of downstream processing steps. Embodiments disclosed herein also include those in which reaction by-products generated by application of the etch solution are removed.

While the above embodiments have been described with reference to a fusion down draw process, it is to be understood that such embodiments are also applicable to other glass forming processes, such as float processes, slot draw processes, up-draw processes, and press-rolling processes.

It will be apparent to those skilled in the art that various modifications and variations can be made to embodiment of the present disclosure without departing from the spirit and scope of the disclosure. Thus it is intended that the present disclosure cover such modifications and variations provided they come within the scope of the appended claims and their equivalents.

What is claimed is:

1. A method for manufacturing a glass article comprising:
forming the glass article, wherein the glass article comprises a first major surface, a second major surface parallel to the first major surface, and an edge surface extending between the first major surface and the second major surface in a perpendicular direction to the first and second major surfaces;
applying an etch cream to the edge surface of the glass article, wherein application of the etch cream reduces a density of particles on the edge surface.

2. The method of claim 1, wherein the etch cream comprises hydrofluoric acid and hydrochloric acid.

3. The method of claim 2, wherein the method further comprises combining an etch solution and a thickener to make the etch cream, wherein a concentration of hydrochloric acid in the etch solution is at least about twice a concentration of hydrofluoric acid in the etch solution.

4. The method of claim 3, wherein the concentration of hydrofluoric acid in the etch solution is at least about 1.5 molar.

5. The method of claim 4, wherein the concentration of hydrofluoric acid in the etch solution ranges from about 1.5 molar to about 6 molar.

6. The method of claim 4, wherein the concentration of hydrochloric acid in the etch solution ranges from about 3 molar to about 12 molar.

7. The method of claim 3, wherein the concentration ratio of hydrochloric acid to hydrofluoric acid in the etch solution ranges from about 2:1 to about 6:1.

8. The method of claim 1, wherein application of the etch cream reduces a density of particles on the edge surface to less than about 200 per 0.1 square millimeter.

9. The method of claim 1, wherein the etch cream comprises at least about 10% thickener by weight.

10. The method of claim 9, wherein the thickener comprises at least one component selected from the group consisting of polyacrylamides, polyethylene oxides, and ether amines.

11. The method of claim 1, wherein an etch rate of the edge surface upon application of the etch cream is at least about 2 micrometers per minute.

12. The method of claim 1, wherein the step of applying further comprises applying the etch cream at a temperature of at least about 45° C.

13. The method of claim 1, wherein the edge surface is subjected to a beveling process prior to application of the etch cream.

14. The method of claim 1, wherein the step of applying further comprises applying the etch cream by at least one method selected from the group consisting of spraying, misting, dipping, rolling, and brushing.

15. The method of claim 1, wherein the method further comprises washing the etch cream from the edge surface at a temperature of at least about 75° C.

16. The method of claim 1, wherein the step of applying further comprises applying the etch cream at a temperature ranging from about 45° C. to about 60° C.

17. A glass article made by the method of claim 1.

18. An electronic device comprising the glass article of claim 17.
